(19) United States
(12) Patent Application Publication
(10) Pub. No.: US 2004/0125001 A1
(43) Pub. Date: Jul. 1, 2004

(54) Synchronous method and system for transcoding existing signal elements while providing a multi-resolution storage and transmission medium among reactive control schemes

(76) Inventor: Carey Lotzer, Plano, TX (US)

Correspondence Address: Raffi Gostanian, Jr., Jackson Walker L.L.P., Suite 600, 2435 North Central Expressway, Richardson, TX, 75080, US

(21) Appl. No.: 10/735,990

(22) Filed: Dec. 15, 2003

Related U.S. Application Data
(60) Provisional application No. 60/433,394, filed on Dec. 13, 2002.

(51) Int. Cl. H03M 7/00

(52) U.S. Cl. 341/50

(57) ABSTRACT

A system, method, and computer readable medium adapted to transmit a signal, comprises a receiver adapted to receive a first signal and produce a buffered signal; a transform adapted to produce pulses and index segments based on the buffered signal, wherein the transform is coupled to the receiver; a collection module adapted to receive and store the pulses and the index segments; and a transmitter adapted to transmit at least one of a following data from a group consisting of: the produced pulses and index segments; and the stored pulses and index segments.

### CROSS REFERENCE TO RELATED APPLICATIONS

The present commonly assigned patent application is related to and claims the benefit of U.S. Provisional Patent Application No. 60/433,394, filed on Dec. 15, 2002, entitled A SYNCHRONOUS METHOD FOR TRANSCODING EXISTING SIGNAL ELEMENTS WHILE PROVIDING A MULTI-RESOLUTION STORAGE AND TRANSMISSION MEDIUM AMONG REACTIVE CONTROL SCHEMES, the teachings of which are incorporated by reference herein.

### BACKGROUND OF THE INVENTION

The present invention is generally related to signal conversion, and more specifically, to a synchronous method and system for transcoding existing signal elements while providing a multi-resolution storage and transmission medium among reactive control schemes.

The advent of the Internet has caused businesses to rethink their business models, customer relationships, and internal processes. Technology advances have created new opportunities to reach employees and customers, wherever they are, with information that is tailored to their needs and preferences. This information is often already stored and used in the business, but the delivery system must be re-engineered to exploit the new technology and tailor the content so it is more usable. A common problem associated with this re-engineering is that data or information that is stored in some form on one system, may be needed in a different form by another system.

The user interaction model advanced by the Internet browser, along with portable and interoperable features of new technologies such as the Java language and Extensible Markup Language have created a new opportunity to address this problem with some common techniques. In contrast, the rapid appearance of wireless and other new networks with widely varying characteristics and the preponderance of new devices with a wide variety of capabilities creates new constraints on the solution. Devices that are designed to be easily carried and used in the field trade off some capabilities to gain this portability. To be easily carried, they must be light and small. This requirement limits the types of user interfaces they can support. Large screens and full keyboards are cumbersome; a small screen and telephone keypad are more realistic, although some devices may have only a voice interface. To run on battery power for useful periods of time, power consumption must be carefully managed, forcing the use of designs with little storage and processing capability. To be connected from anywhere requires wireless or intermittent wired connections, which limit the types of interactions and bandwidth available for accessing content.

All of these constraints create difficult challenges in designing a useful system for delivering content to a wide array of devices. However, if such an information delivery system can be created quickly and cost-effectively, and if it integrates with existing information systems, the value to customers can be immense. Transcoding, or adapting content from one form to another, is a key part of meeting these requirements for rapid, inexpensive deployment of new ways to access existing content.

The media signal processing industry first used the term “transcoding” to refer to the task of converting a signal, associated with a television program for example, from one format to another while preserving the content of the program. An example of this would be converting the National Television System Committee standard, used in America and Japan, to the Phase Alternating Line standard, used in much of the rest of the world. Although the term has lately been used to mean many different things, the term transcoding is utilized here to refer to the tasks of summarizing or filtering (which modify content without changing its representation) and translating, or converting, content from one representation to another.

An example of transcoding can be found in lossy image compression, which is generally performed in the manner described herein. An input signal of uncoded data is received and down-sampled using a color transform then converted to another domain, i.e., from the spatial domain to the time domain. The signal is then quantized using fixed steps based on given user parameters and then passed to an entropy coder which collects redundant data and finally stores the data to a file.

The process is reversed to recover the data. In this example of the lossy compressed image file, a datum would be read into a memory, uncompressed by reversing the entropy encoding (thus forcing the resulting coefficients through the time domain transform back to the spatial domain), up-sampling the data using the reverse of the applied color transform, then storing the resulting uncoded values. A similar process can be used to retrieve the un-coded pixels from any previously compressed file or meta-file.

Once this datum is recovered, a transcoding operation may be employed in order to reduce the image bitrate or to place the image into a different format. This process is more suitable for the device for which it is targeted. However, due to the quantization process performed during the first and second signal encodings, the recovered information is much lower in quality than the original. This is evident by the existence of distortions (artifacts), which appear in the reconstructed signal as a result of the quantization process, usually characterized by a Gibbs phenomenon or contrast loss and/or blending. Performing still multiple iterations of this compression process produces additional artifacts compounded on the previous ones thereby further degrading signal quality.

In addition, this method of compression does not provide the ability to extract an infinite array of signal dimensions from a single binary segment and additively sum the results during reconstruction. For this reason, multiple signals require additional memory device storage to present a finite organization of possibilities available to the user over the requirements of the original. For example, to store an image for varying resolutions, usually a thumbnail, small, medium, large and original copy is archived so that users, having varying transmission capabilities, have the ability to locate and retrieve the image dimension of their preference or need. The same is true for audio files as well as video. Therefore, what is needed is a method and system that overcomes these problems and limitations.

### SUMMARY OF THE INVENTION

The present invention enhances digital waveform transmission and storage by collapsing signals into smaller time-bandwidth pulse segments thereby providing faster delivery (smaller signature in the time/transmission domain) through transmission channels and having the ability to re-compress a given compressed signal even further in order to reduce its already compressed size while minimizing artifacts in the signal structure. As a result, initial arrivals of the coded pulses may be reconstructed once received at the appropriate transponder in a more expedient manner than is available to date which may occur before the entire signal needs to or even has a chance to be received by the reconstructing transponder. As such, an enhanced transmission solution comprised of the most significant data characterized as first arrival for the necessity of advanced vision capability (even in the event of broken or impaired signal transmission is all that is being provided).

In order to achieve such a solution, the present invention provides characteristic and critically controlled output of specified waveform signatures as desired by the reconstructing transponder. Inputs to the signal handling method include time-bandwidth product, waveform length, sidelobe suppression, etc. These input requirements may be further simplified using a statistical modeling technique that considers the input information, the transform performance and the additional storage and transmission savings desired. The described operably coupled transforms are used to compress signals into more compact pulse segments for more efficient transmission and/or storage and indexing. The resulting signature is then passed to a module such as a vector waveform generator and delivered to the output device. The output signal generation is taken to have negligible error with minimal coefficient loss.

The attribute of separating the frequency fluctuations into neat compartments produces several benefits. These include the re-orientation of like datum that provides high compressibility. In addition, the stacking orientation of the iterative process provides true finite representation of the spatial information of the image as numerous points within the storage matrix. This lends to a large benefit for the reconstruction process whereby the pulse can be retrieved in a compressed state and deciphered at N-number of quantization levels so that ranges from thumbnail-sized images to the image in its entirety and any amount in-between can be recovered and reconstructed for the user by simply summing the respective coefficient transmissions together. This attribute also lends itself to unique and “smart” network design solutions. These are briefly discussed herein.

In the present invention, this method and system is additionally applied to other signals and systems such as full-motion low and high-bitrate video signals, single and multichannel audio, virtual-reality systems and still-frame coding for archival, analysis and transmission purposes. The present invention may also be utilized to handle rotations, shadows and shears in a given domain and is further viable for audio and textual coding, image sharpening, noise removal, image detail localization, improvement of impaired and mechanically aided natural vision and auditory senses, among other signal processing applications.

In one embodiment, the present invention comprises a method for converting a signal, comprising: receiving, by a pre-decoder, at least one input signal; identifying, by the pre-decoder, the received input signal; transmitting, by the pre-decoder, the identifier to at least one of a following module, based on the identifier, from a group consisting of: at least one decoder; and a first encoder. The method further comprises transforming, by the identified decoder, the received input signal into a first un-encoded signal; transmitting the first un-encoded signal to at least one encoder, based on the identifier, by the at least one decoder; transmitting a second un-encoded signal, by the pre-decoder, to the first encoder; and converting, by the at least one encoder, the first un-encoded signal into a first encoded signal; and converting, by the first encoder, the second un-encoded signal, into a second encoded signal.

In another embodiment, a system adapted to transmit a signal, comprising: a receiver adapted to receive a first signal and produce a buffered signal; a transform adapted to produce pulses and index segments based on the buffered signal, wherein the transform is coupled to the receiver; a collection module adapted to receive and store the pulses and the index segments; and a transmitter adapted to transmit at least one of a following data from a group consisting of: the produced pulses and index segments; and the stored pulses and index segments.

In a further embodiment, a system adapted to transmit a signal, comprising: a receiver adapted to receive a first signal; a resolution module adapted to produce an un-coded signal based on the first signal, wherein the receiver is coupled to the resolution module; a transform adapted to produce pulses and index segments based on the un-coded signal, wherein the transform is coupled to the resolution module; a collection module adapted to receive and store the pulses and the index segments; a transmitter adapted to transmit at least one of a following data from a group consisting of: the produced pulses and index segments; and the stored pulses and index segments; and at least the memory coupled to at least one of a following element from a group consisting of: the receiver; the resolution module; the transform; the collection module; and the transmitter.

In yet another embodiment, a pre-quantization module, comprising: means for filtering at least one of a following first signal from a group comprising of: an un-encoded signal; and an encoded signal; means for filtering a second filtered signal, wherein the second filtered signal is related to the first filtered signal; means for filtering a third filtered signal, wherein the third filtered signal is related to the second filtered signal; and means for transforming the third filtered signal, wherein the transformed third filtered signal is output from the pre-quantization module.

In yet a further embodiment, a shear energy module, comprising: means for receiving at least one of a following pulse band from a group comprising of: a significant pulse band; and an insignificant pulse band; means for averaging amplitudes of the pulse band; means for transforming the averaged pulse into a phase coded pulse; and means for reflecting the phase coded pulse onto itself.

In yet another embodiment, a computer readable medium comprising instructions for: outputting a signal request; transmitting the signal request; receiving an input waveform and error enhancing signal based on the transmitted signal request; transforming the received input waveform and error enhancing signal from a phase coded pulse to a presentation signal; and transmitting the presentation signal based on the transformed input waveform and error enhancing signal.

In yet a further embodiment, a computer readable medium comprising instructions for: receiving an output waveform and error enhancement signal; producing enhanced coefficient trees based on the received output waveform and error enhancement signal; un-aligning the enhanced coefficient trees; and producing a transformed pulse based on the un-aligned enhanced coefficient trees.

### BRIEF DESCRIPTION OF THE DRAWINGS

FIG. 1 is a block diagram of the system overview in accordance with an exemplary embodiment of the present invention;

FIG. 2 is a block diagram of the encoder portion of the system in accordance with an exemplary embodiment of the present invention;

FIG. 3 is a high-level block diagram of the system demonstrating the versatility of the system having a resolution module and a single memory in accordance with an exemplary embodiment of the present invention;

FIG. 4 is a high-level block diagram of the system demonstrating the versatility of the system without a resolution module and without a memory in accordance with an exemplary embodiment of the present invention;

FIG. 5 is a high-level block diagram of the system demonstrating the versatility of the system without a resolution module but with a single “floating” memory utilized by multiple system modules in accordance with an exemplary embodiment of the present invention;

FIG. 6 is a block diagram describing the detail of the pre-quantization module from FIG. 2 in accordance with an exemplary embodiment of the present invention;

FIG. 7 is a block diagram describing the detail of the energy separation module from FIG. 2 in accordance with an exemplary embodiment of the present invention;

FIG. 8 is a block diagram describing the detail of both the significant shear energy and insignificant shear energy modules located in FIG. 2 in accordance with an exemplary embodiment of the present invention;

FIG. 9 is a block diagram describing the reconstruction of the system in accordance with an exemplary embodiment of the present invention; and

FIG. 10 is a block diagram describing the portion of the end-user processing module in accordance with an exemplary embodiment of the present invention.

### DETAILED DESCRIPTION OF THE INVENTION

System Overview

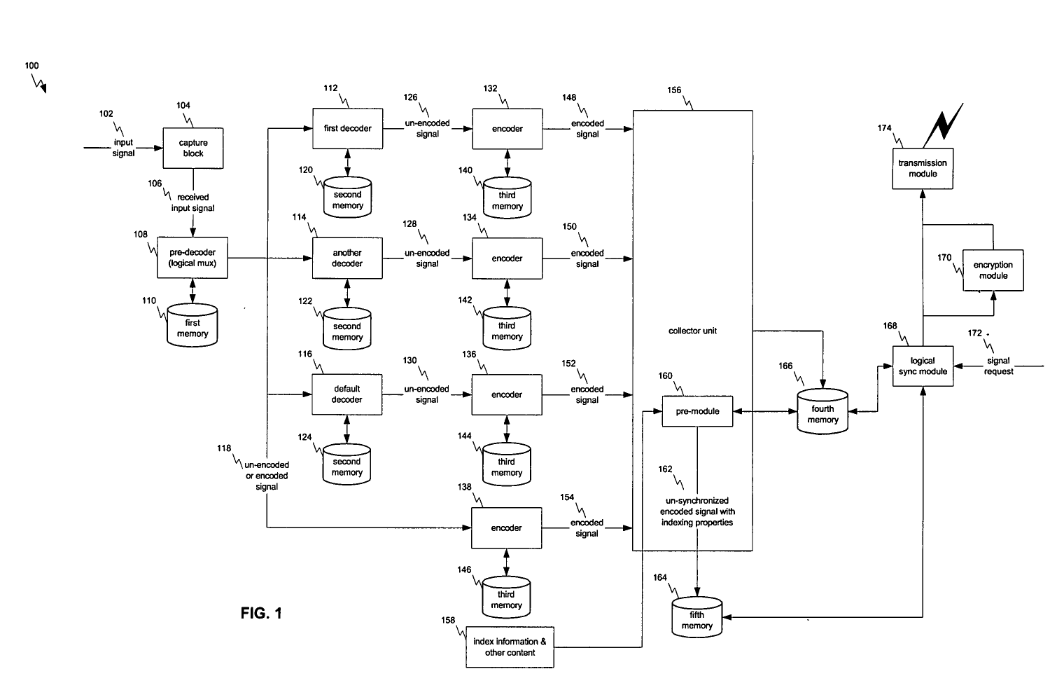

Referring to FIG. 1, the system 100 of the present invention includes an input signal 102. This input signal 102 is captured by the capture block 104. Once the signal 102 has been captured a received input signal 106 is transmitted to a pre-decoder 108. This pre-decoder 108 acts as a logical multiplexer which may either separate the signal into several sub-signals or pass the signal in its entirety to one of several modules. Such modules may include a first decoder 112, another decoder 114, a default decoder 116, an encoder 138, or other modules of the present invention. In addition, this pre-decoder 108 may store one or several sub-signals or the entire signal in a first memory 110 in order to receive additional information if needed. Once the signal is received by a first decoder 112, another decoder 114 or a default decoder 116, the signal is converted to an un-encoded signal 126-130. This un-encoded signal 126-130 is transmitted by a decoder 112-116 to its respective encoder 132-136 for further processing. At this juncture, the un-encoded signal 126-130 is usually much larger in length than the originating input signal 102.

If the signal transmitted by the pre-decoder 108 can be accepted by the encoder 138, it is delivered to the encoder without first being transmitted to one of the decoders 112-116. At any time, the first decoder 112 may utilize a second memory 120, the another decoder 114 may utilize a second memory 122, or the default decoder may utilize a second memory 124. Although depicted as separate memories, the second memories 120-124 may be a common memory.

If the first decoder 112 received an input signal from the pre-decoder 108, the un-encoded signal 126 is transmitted by the first decoder to the encoder 132. The encoder 132 may utilize a third memory 140 as the un-encoded signal is being processed. Once the encoder 132 has processed the un-encoded signal 126, it transmits the encoded signal 148 to a collection unit 156. Likewise, if another decoder 114 received an input signal from the pre-decoder 108, the un-encoded signal 128 is transmitted by another decoder to the encoder 134. The encoder 134 may utilize a third memory 142 as the un-encoded signal is being processed. Once the encoder 134 has processed the un-encoded signal 128, it transmits the encoded signal 150 to the collection unit 156. In addition, if the default decoder 116 received an input signal from the pre-decoder 108, the un-encoded signal 130 is transmitted by default decoder to the encoder 136. The encoder 136 may utilize a third memory 144 as the un-encoded signal is being processed. Once the encoder 136 has processed the un-encoded signal 130, it transmits the encoded signal 152 to the collection unit 156. In the case that the pre-decoder 108 has transmitted the un-encoded or encoded signal 118 to encoder 138, encoder 138 processes the signal and may utilize a third memory 146 as needed. Although depicted as separate memories, the third memories 140-146 may be a common memory. Once the encoder 138 has processed the input signal 118, the encoder 138 transmits the encoded signal 154 to the collector unit 156.

The collector unit 156 coordinates the multitude of signals including the encoded signals 148-154. Once these signals are collected, they are re-multiplexed together and then transmitted to a pre-module 160 within the collector unit 156. The collection unit 156 may also store indexing information in a fourth memory 166 for quick retrieval usage by the pre-module 160 and the logical sync 168. The pre-module 160 takes the index information and other content 158 and produces the un-synchronized encoded signal with indexing properties 162. The un-synchronized encoded signal with indexing properties 162 is used to reproduce the outgoing signal tailored to the details of the signal request 172 received by the logical synchronization module 168. Once the signal request 172 has been received by the logical sync module 168, the logical sync module determines and dynamically synchronizes the content array and resolution block size of the content array. Once the logical sync module 168 has determined these attributes of the given content, the content is retrieved from a fifth memory 164 by the logical sync module and transmitted to either an encryption module 170 or to a transmission module 174 directly. If the content has been transmitted to the encryption module 170, the encryption module 170 processes the content and then transmits the encrypted content to the transmission module 174. Although depicted as separate memories 110, 120-124, 140-146, 164 and 166, these can be combined into one memory and may be directly and/or indirectly accessed.

High-Level System Block Diagrams

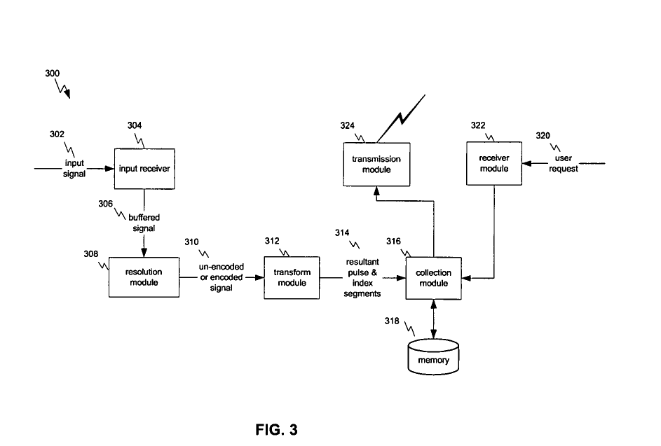

Referring to FIG. 3, a system 300 of the present invention includes a resolution module 308 and a fixed storage memory 318. Once an input signal 302 is received by an input receiver 304, the signal is transmitted as a buffered signal 306 by the input receiver, to a resolution module 308 for further processing. The resolution modules 308 receives the buffered signal 306 and transmits an un-encoded or encoded signal 310 to a transform module 312. The transform module 312 converts the signal 310 to a series of pulses and generates index segments, the resultant pulse and index segments 314, needed for the reconstruction of the pulse segments. Once the resultant pulse and index segments 314 have been produced, the transform module 312 transmits them to the collection module 316. The collection module 316 stores the resultant pulse and index segments 314 to a memory 318. If a user receiver 322 receives a user request 320 after the collection module 316 has successfully stored the resultant pulse and index segments 314 into the memory 318, the user receiver specifies to the collection module the manner in which the pulse and index segments 314, or a portion thereof, should be re-combined to form the output content tailored to the user request signal 320. Once the pulse and index segments 314, or a portion thereof, have been recombined by the collection module 316, the collection module transmits the modified content to a transmitter module 324 for distribution as specified in the user request signal 320.

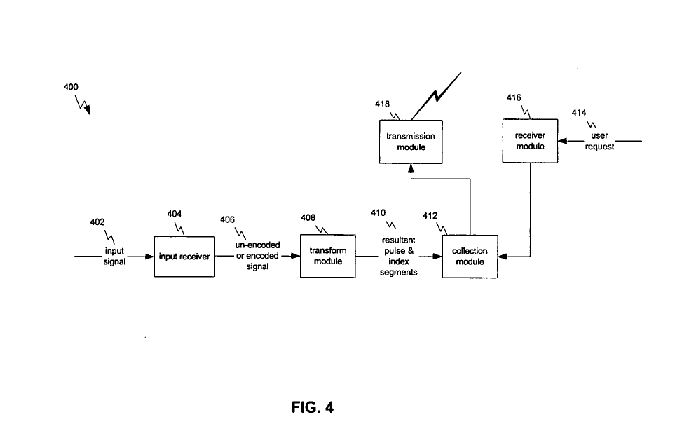

Referring to FIG. 4, the system 400 of the present invention does not include a resolution module 308 or a fixed storage memory 318. Once an input signal 402 is received by an input receiver 404, the signal is transmitted as an un-encoded or encoded signal 406 to a transform module 408. The transform module 408 converts the signal to a series of pulses and generates index segments, the resultant pulse and index segments 410, needed for the reconstruction of the signal. Once the resultant pulse and index segments 410 have been produced, the transform module 408 transmits them to the collection module 412. The collection module 412, having previously received a user request 414 from the user receiver 416, transmits only a needed portion of the re-generated content to a transmitter 418 for distribution to one or more devices and discards any unneeded material.

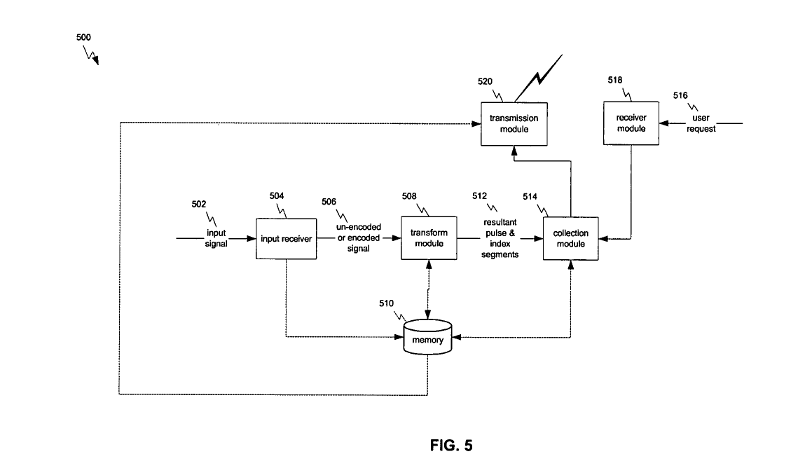

Referring to FIG. 5, the system 500 of the present invention does not include a resolution module 308 yet may contain a memory 510 which can be universally utilized by the system. Once an input signal 502 is received by an input receiver 504, the signal is transmitted as an un-encoded or encoded signal 506 to a transform module 508. The transform module 508 converts the signal to a series of pulses and generates index segments, the resultant pulse and index segments 512, needed for the reconstruction of the signal. Once the resultant pulse and index segments 512 have been produced, the transform module 508 transmits them to the collection module 514. Once the collection module 514 receives a user request 516 from a user receiver 518, either before or during the time when the resultant pulse and index segments 512 are being produced, the collection module may transmit only the needed portion of the re-generated content based on the user request 516. The collection module may transmit the material to a transmitter 520 for distribution to one or more devices and/or store the material, or a portion thereof, in the memory 510. Once the material has been stored in the memory 510 by the collection module 514, a series of asynchronous user requests 516 may be received by the user receiver 518 and acted upon as previously noted. In addition to the memory 510 being utilized by the collection module 514, each independent module including the input receiver 504, the transform module 508, or the transmitter 520 may voluntarily utilize the memory 510 as needed.

The Encoder, Pre-Quantization, Energy. Separation, and the Significant and Insignificant Shear Energy Module

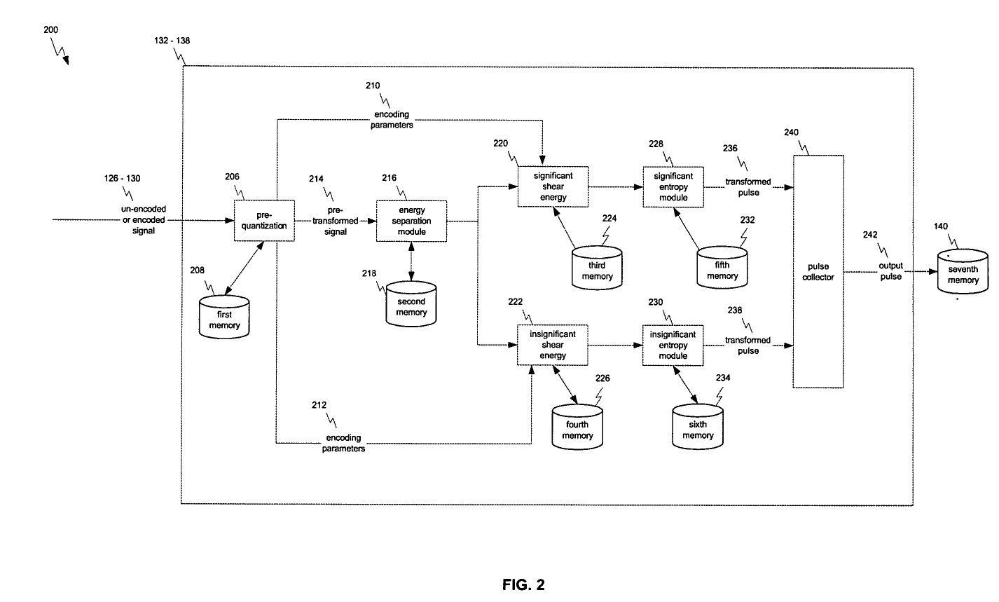

Referring now to FIG. 2, the encoder system 200 of the present invention, which is a detailed view of the encoder 132, includes receiving an un-encoded or encoded signal 126 by a pre-quantization module 206 which provides an initial enhancement logic for a received datum. These data may need to be enhanced due to aliasing, noise and/or edge artifacts and produce a pre-transformed signal 214 based on a signal array (an ordered collection of numeric samples corresponding to a series of intensities). Each data value has a given intensity, which can be measured along a Cartesian or polar coordinate system where the y value corresponds to amplitude. The pulse propagation can also be mapped against the x-axis and used as the magnitude. The input rate of the given signal is derived from both the scalar quantization and the block data dimensions. The pre-quantization module 206 may store portions of the signal in a first memory 208 before producing a pre-transformed signal 214. In addition, the pre-quantization module 206 collects encoding parameters 210 and 212 which are used later for the significant shear energy and insignificant shear energy modules 220 and 222 respectively. Once the pre-transformed signal 214 has been derived, the pre-quantization module 206 transmits the pre-transformed signal 214 to an energy separation module 216 in order to separate the energy fluctuations within the pre-transformed signal. During the process of separation, the energy separation module 216 may utilize a second memory 218. Once the pre-transformed signal 214 has been separated in the energy separation module 216, the energy separation module transmits the resulting significant shear energy to the significant shear energy module 220 and transmits the insignificant shear energy to the insignificant shear energy module 222. The significant shear energy module 220 uses a significant sub-pulse transform to further remove insignificant energy from the significant energy signal. Further, the insignificant shear energy module 222 reduces the insignificant energy signal by applying an insignificant sub-pulse transform. The significant shear energy module 220 may utilize a third memory 224 as it produces the output signal. Likewise, the insignificant shear energy module 222 may utilize a fourth memory 226 as it produces its output signal.

Once the significant shear energy module 220 has produced the output signal, the significant shear energy module transmits the output signal to a significant entropy module 228. The significant entropy module 228 may store portions of the resulting transformed pulse 236 until it has been completed. Once the transformed pulse 236 has been completed, the significant entropy module 228 transmits the transformed pulse to a pulse collector 240. Likewise, once the insignificant shear energy module 222 has produced the output signal, the insignificant shear energy module transmits the output signal to an insignificant entropy module 230. The insignificant entropy module 230 may store portions of the resulting transformed pulse 238 until it has been completed. Once the transformed pulse 238 has been completed, the insignificant entropy module 230 transmits the transformed pulse to the pulse collector 240. Once the pulse collector 240 receives the transformed pulses 236 and they are combined into a single output pulse 242 and transmitted to a seventh memory 140. Although depicted as separate memories 208, 218, 226, 232, 234 and 140, these can be combined into one memory and may be directly and/or indirectly accessed.

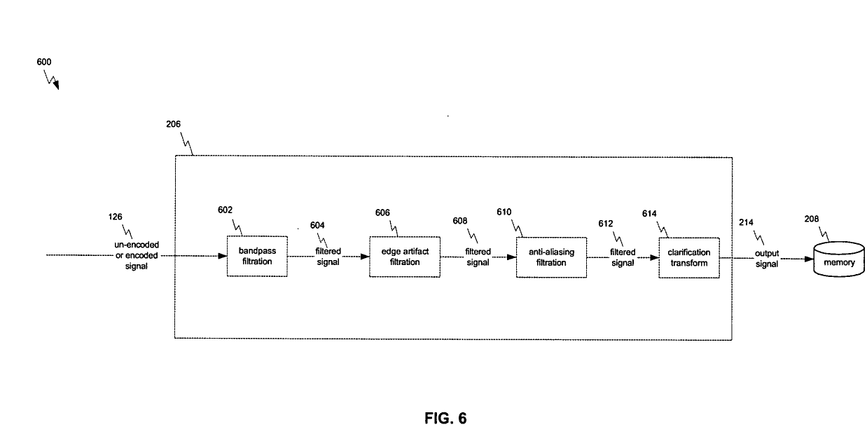

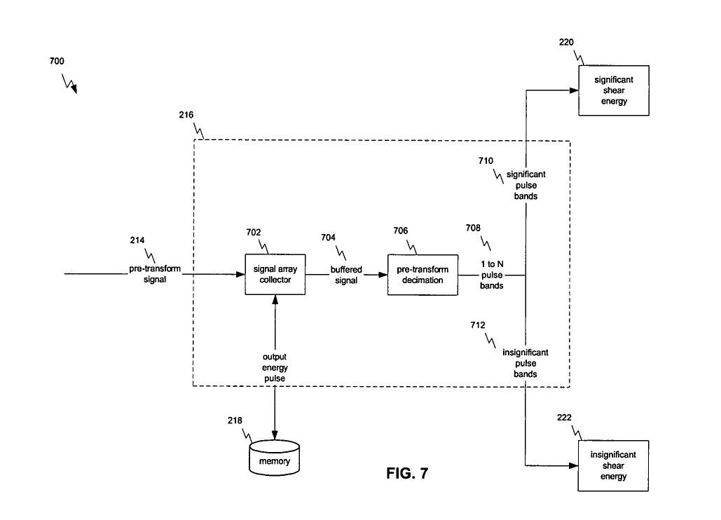

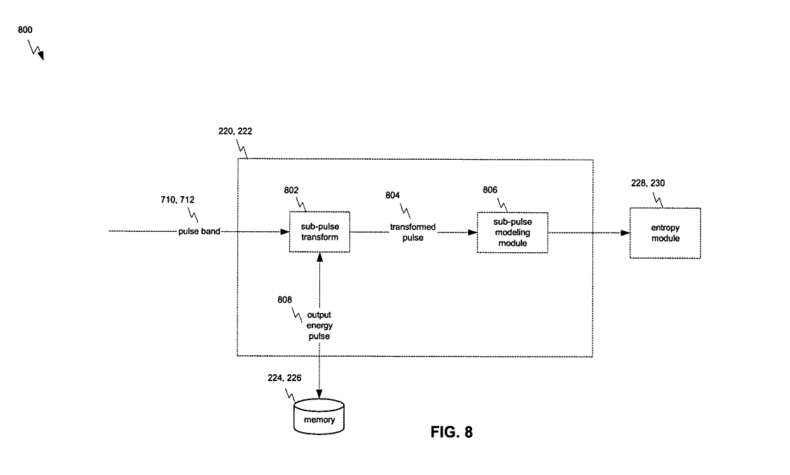

Referring to FIG. 6, FIG. 7 and FIG. 8, a pre-quantization module 600, an energy separation module 700 and significant and insignificant shear energy modules 800 are described in further detail.

Referring now to FIG. 6, the pre-quantization module 600 of the present invention discloses an un-encoded or encoded signal 126 being received by a noise filtration module 602. The un-encoded or encoded signal 126 is filtered using adaptive high and low-pass filters within the noise filtration module 602. Once the filtered signal 604 has been produced, the noise filtration module 602 transmits the filtered signal to an edge artifact filtration module 606 which enhances the frequency characteristics of the edges within the given signal. Once the edge artifact filtration module 606 produces the filtered signal 608 it transmits the filtered signal to an anti-aliasing filtration module 610. Once a filtered signal 612 has been produced in the anti-aliasing filtration module 610 it transmits the filtered signal to a clarification transform 614.

The initial task of the clarification transform 614 is to reduce the given data using a pre-transform in order to alter the aspect and size (duration) of the given pulse to an orthogonal matrix for faster processing and additional efficiency. To achieve this, the datum is passed through a higher domain transform which alters the pulse aspect from NM to PP where P is an arbitrary collection of data elements having uniform binary density. The datum may have consistent patterns of repeating information which appear in the majority of natural and synthetic image data. The purpose of this higher domain transform is to locate repeating objects within a harmonic range which occur in an additive sinusoidal frequency, marked by diminishing or increasing frequencies over time. This transform prepares objects shown at an angle in the pulse for the energy transform so that artifacts are reduced during the reconstruction process and provides for a substantial compression capability. Generally, non-frequency propagating data is obscured in the transform although this datum is generally minimal in many natural-occurring images. Therefore, the transform is only performed on pulses that can truly benefit from the process. Otherwise, the pulse perspective remains intact. Just as Doppler shifts occur in nature for audio signals, for example when a standing object senses the whistle of a moving locomotive, the same occurs for pulse signals at a spatial level. These repeating patterns, such as a railroad track, the side of a building or a football field, have a particular frequency associated with it from a beginning of the pulse to its vanishing moment (even if the vanishing moment may be off-screen). This phenomenon may also be exploited for temporal coding applications such as video. This frequency can be determined and modeled so that a series of coefficients can be derived from the modeled datum and used to determine redundancy in entire pulse patterns. Once the clarification transform 614 has produced the output signal 214 it is transmitted to a memory 208, for example.

Referring to FIG. 7, the energy separation module 700 of the present invention depicts a pre-transform signal 214 being received by a signal array collector 702. As the pre-transform signal 214 is collected in separate arrays, the output energy pulse is transmitted to a memory 218 until the signal array collector 702 has received a complete pre-transform signal 214. Once the output energy pulse has been collected into a buffered signal 704, the signal array collector 702 transmits the buffered signal to the pre-transform decimation module 706. The pre-transform decimation module 706 converts the buffered signal 704 to an alternative domain; each discrete portion of the resulting transformed signal delta is then processed using a 2 dimensional analysis of particular energies and respective intensities taken that delta is the set of a1, b1, c1, and d1. This series of transforms produces subsets of the transformed signals called sub-pulses where each sub-pulse a1, b1, c1, d1 has M/k horizontal points and N/k vertical points (where k is the divisible number of sub-iterations corresponding to the pulse derivative). Sub-pulse c1 is created by computing trends along the horizontal axis of delta followed by computing trends along the vertical axis; so it is an averaged, lower resolution version of delta. Since a 1D trend sub-pulse is sqrt(2) times an average of successive values in a signal, the 2D trend sub-pulse c1 is equal to 2 times an average of a small square containing adjacent values from the pulse delta. Therefore, the values of c1 can be shown as scalar products of the delta with scaling signals. Sub-pulse a1 is created by computing trends along the horizontal axis of the delta followed by computing energy fluctuations along vertical points. Consequently, wherever there are horizontal edges in a pulse, the fluctuations along vertical points are used to detect these edges. In addition, any vertical fluctuations are left out of this pulse a1 so that a1 is a collection of horizontal energy fluctuations. Sub-pulse d1 is similar to a1 with the exception of the roles being switched for horizontal energy fluctuations to vertical ones.

It is also of interest that all horizontal traces are left out of the filter so that this is referred to as a collection of vertical energy fluctuations. Sub-pulse b1 is the diagonal energy fluctuations along both horizontal and vertical axes. The horizontal and vertical fluctuations are erased where these energies are relatively more constant and the true diagonal details are emphasized. The energies of a pulse are the direct summation of the energies separated into the horizontal and vertical axes. Since the 1D transform of the horizontal axis preserves the energies of the row vectors, the pulse obtained for a1 will have the same energy of the original pulse supplied to the transform. Likewise, the same is true for the d1 sub-pulse. The process of obtaining the four sub-pulses can be continued N times in order to further produce incremental compression and storage efficiency until the inevitable rounding errors of the computing device basically decimate the energy levels needed to produce a suitable reconstructed pulse. In this manner, the pre-transform decimation module 706 produces 1 to N pulse bands 708. As these 1 to N pulse bands 708 are generated, they are separated by the given frequency levels in order to compartmentalize the resulting sub-pulse segments into significant and insignificant pulse bands 710 and 712. Once the significant and insignificant pulse bands 710 and 712 have been generated, the pre-transform decimation module 706 transmits the pulse bands to their respective significant and insignificant shear energy modules 220 and 222.

Referring to FIG. 8, the significant and insignificant shear energy modules 800 of the present invention depict a significant or insignificant pulse band 710 or 712 being received by the sub-pulse transform module 802. The sub-pulse transform module 802 processes the significant or insignificant pulse band 710 or 712 by deriving first averages over the amplitude of the pulse then transforming the pulse to a phase signal so that a thorough statistical analysis of the pulse may be accomplished. Once completed, the pulse signal is transformed to the transformed domain and phase coded using the filter coefficients derived in the previous computations. Once the initial phase coding of the pulse is complete, the pulse is brought upon itself as a reflected signal for the intention of determining specific intensity groupings targeted for separation due to redundancy. At this point, separate high-pass and low-pass filter coefficients from the original reflected pulse are stored for later use in coding the derived coefficient trees based on the signal significance at varying levels of frequency measuring points. During this process, the sub-pulse transform module may utilize a memory 224 or 226 for the purpose of storing the partial output energy pulse 808 until the transformed pulse 804 has been completely produced. Once the significant or insignificant pulse band 710 or 712 has been transformed by the sub-pulse transform module 802 into the transformed pulse 804, the sub-pulse transform module 802 transmits the transformed pulse to a sub-pulse modeling module 806.

In the interest of supplying the most generous collections of redundant coefficients to the entropy module 228 and 230, the sub-pulse modeling module 806 produces a set of continuous time models which are chained together based on statistical analysis of the repeated datum by realigning the received phase coded pulse. Therefore, if a point at (x, y) changes at a rate r(t), an occurrence between times t and t+dt has probability about r(t)dt when dt is small. When r(t) is a constant r, the times t[i] between occurrences are independent exponentials with mean 1/r, and have a Poisson process with rate r. These chains in continuous time are defined by giving the rates q(x, y) at which jumps occur from state x to state y. In many cases q(x, y) can be written as p(x, y)Q where Q is a constant that represents the total jump rate. In this case, the chain is constructed by taking one step according to the transition probability p(x, y) at each point of a Poisson process with rate Q. If the information about the exponential holding times in each state is discarded, the resulting sequence of states visited is an embedded discrete time chain. Therefore, the total flip rate Q at any one time is a multiple of the number of sites, CQ. Since the number of sites is typically tens of thousands, very little accuracy is lost in simulating TCQ steps and calling the result the state at time T. To build the discrete time chain, various transitions with probabilities proportional to their rates must be carefully picked. In this system, sites are picked at random, applying a stochastic updating rule, and then repeating the procedure to fully accomplish the selection process. This continuous time convolution is referred to as asynchronous updating in order to distinguish it from the synchronous updating of the discrete time process that updates all of the sites simultaneously. Once the sub-pulse modeling module 806 produces the datum chain, it is transmitted to the respective entropy module 228 or 230.

Once received by the respective entropy module 228 or 230, this datum chain is used as the probability model to the entropy encoding tree in the entropy module 228 or 230 so that the symbols are encoded from the transformed source in an optimal fashion. To do this, each symbol is assigned a code x(i) with length L(i)=−log(2) p(i), where p(i) is the probability of the symbol's occurrence. This produces the transformed pulse 236 or 238 based on the pulse significance.

The Reconstruction

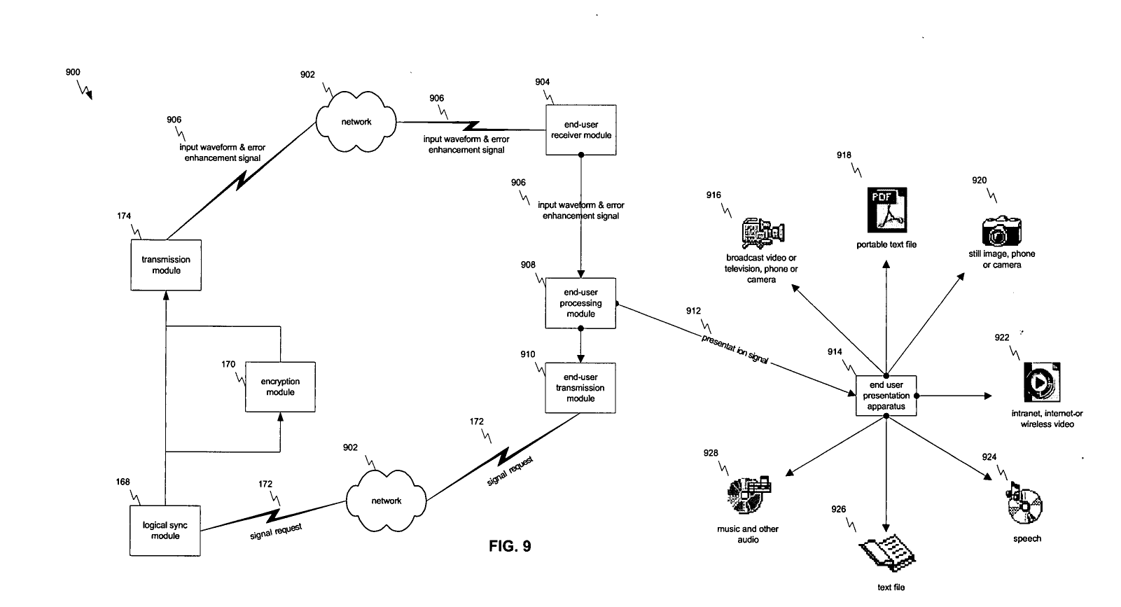

Referring to FIG. 9, the reverse of the aforementioned process is described in the present invention as a reconstruction 900. The reconstruction 900 provides an output waveform such as a presentation signal 912 which may be an image 920, or text 918 or 926, to the viewing user, a sound 924 or 928 to the human ear, or moving images for video 916 or 922, among other examples. An end-user processing module 908 transmits a signal request 172 to the end-user transmission module 910. The signal request 172 is then transmitted by the end-user transmission module 910 across a network 902 to the logical sync module 168. The logical sync module 168 receives the signal request 172 that is then accessed by the logical sync module 168 for processing. Once the logical sync module 168 retrieves the intended pulse, the pulse or a portion of it is encrypted in the encryption module 170 and transmitted to the requesting transponder using the transmitter 174 over the network 902 or other medium. Once the requested pulse or a portion of it arrives over the network 902 or other medium at the intended transponder, such as a desktop browsing system or other end-user system, which may include an end-user receiver module 904, an input waveform and enhancement signal 906 is transmitted by the end-user receiver module 904 to the end-user processing module 908 to be decoded post-transmission using various first arrival segments. Simultaneous transmission of the error enhancement signal 906 is also presented to the receiver embedded within the same pulse described herein as the input waveform and enhancement signal. The end-user processing module 908 decodes the input waveform and error enhancement signal 906 into its own format, a format of its original type or a format of another type which is optimized for a target device 916, 918, 920, 922, 924, 926, 928 or other as the presentation signal 912. Once the presentation signal 912 has been produced, it is transmitted by the end-user processing module 908 to the end-user presentation apparatus 914 (i.e., an electronic device).

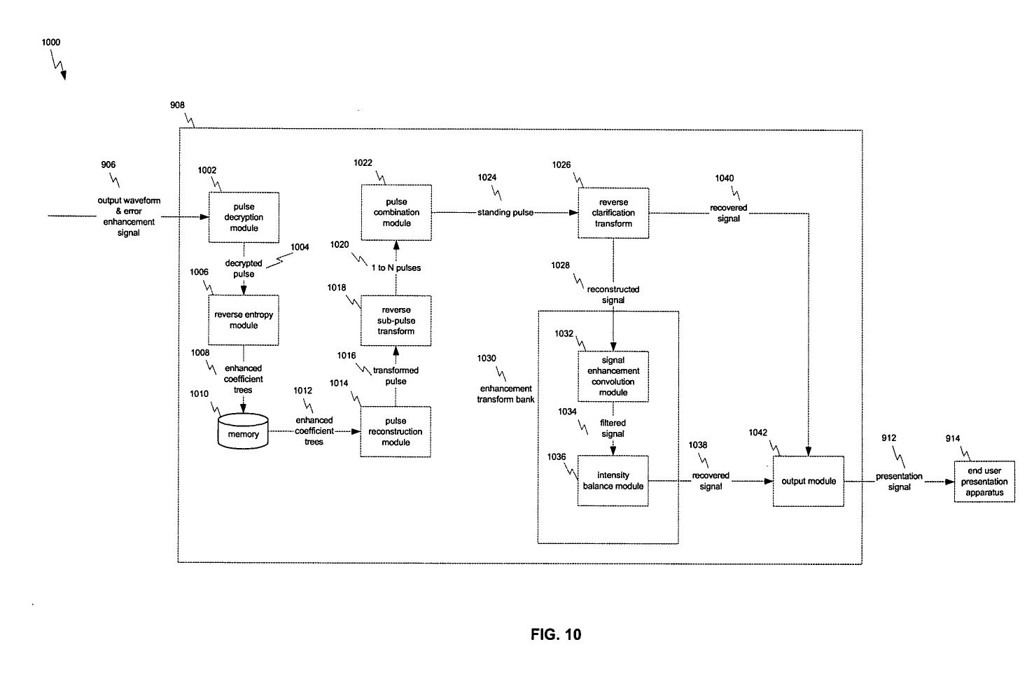

Referring to FIG. 10, an end-user processing module 908 depicts an output waveform and error enhancement signal 906 being received by the system 1000 of the present invention. Once the pulse decryption module 1002 receives the output waveform and error enhancement signal 906, the pulse decryption module 1002 reverses the encryption applied to the pulse if it is encrypted and transmits the decrypted pulse 1004 to the reverse entropy module 1006. If the pulse has not been encrypted, the output waveform and error enhancement signal 906 is transmitted directly to the reverse entropy module 1006 as is. The reverse entropy module 1006 produces a series of enhanced coefficient trees 1008 and an error recovery signal. A memory 1010 is assigned in relation to the needs relating to both signals encompassing the enhanced coefficient trees 1008 and the error recovery signal. A pulse reconstruction module 1014 reads the enhanced coefficient trees 1008 and the error recovery signal from the memory 1010. The coefficient trees are re-sorted and recovered in the pulse reconstruction module. Another function of the pulse reconstruction module 1014 involves applying the error recovery signal to the re-sorted coefficient trees. As the first arrival data is read from the memory 1010 and is reconstructed, the pulse becomes enhanced and represents an incremental improvement in comparison to the original signal. At this point, a parent and child relationship is established where the parent is the locus and the children are the multiple digital pulses. The parent of the re-sorted signal model is regenerated from the coded coefficient collection in the pulse reconstruction module 1014 into the transformed pulse 1016. Once the transformed pulse 1016 has been reconstructed it is transmitted by the pulse reconstruction module 1014 to the reverse sub-pulse transform 1018. The reverse sub-pulse transform 1018 receives the transformed pulse 1016, in which information is derived from the header of the incoming coefficient transmission that provides the amplitude averages collected during the coding sequence. These are applied to the transformed pulse 1016 once the inverse transform process in the reverse sub-pulse transform 1018 has completed producing 1 to N number of pulses 1020. The reverse sub-pulse transform 1018 transmits the 1 to N pulses 1020 to the pulse combination module 1022. It is in the pulse combination module 1022 that the average intensities and the high and low-pass filter coefficients are used to recover the standing pulse 1024. Once the standing pulse 1024 has been produced, the pulse combination module 1022 transmits the standing pulse to the reverse clarification transform 1026. The standing pulse 1024 is then re-sampled using the transform, which returns the standing pulse 1024 values into their original signal intensity, which is the reconstructed signal 1028 or 1040.

The reverse clarification transform 1026 decides on the needs of the pulse and transmits the reconstructed signal 1028 to the enhancement transform bank 1030 or transmits the reconstructed signal 1040 directly to the output module 1042. The enhancement transform bank 1030 contains a series of transforms used to further excite the signal where it is needed. These transforms include the signal enhancement convolution module 1032, the intensity balance module 1036, and may include others. Upon full reconstruction, the enhancement transform bank 1030 transmits the recovered signal 1038 to the output module 1042. At this point the reconstructed signal 1042 may be left as is or returned to another form more suitable to the targeted device. This resulting data set, the presentation signal 912, is then fully delivered to the end-user presentation apparatus 914 (i.e., an electronic device) for general use. At this point, memory allocated for the reconstruction process is released and the presentation signal 912 is available to be seen and/or heard.

Although an exemplary embodiment of the present invention has been illustrated in the accompanied drawings and described in the foregoing detailed description, it will be understood that the invention is not limited to the embodiments disclosed, but is capable of numerous rearrangements, modifications, and substitutions without departing from the spirit of the invention as set forth and defined by the following claims.

What is claimed is:

1. A method for converting a signal, comprising:
receiving, by a pre-decoder, at least one electronic input signal from a group consisting of:
video;
audio;
text; and
multi-media;
identifying, by the pre-decoder, the received input signal;
transmitting, by the pre-decoder, the identifier to at least one of a following decoder, based on the identifier, from a group consisting of:
the first decoder;
another decoder; and
at least one encoder;
wherein at least one of a following coupling occurs from a group consisting of:
the decoder and the pre-decoder operably coupled to each other; and
the pre-decoder and the encoder operably coupled to each other;
wherein the other decoder is operably coupled to the pre-decoder;
transforming, by the identified decoder, the received input signal into a first un-encoded digital signal;
transmitting the first unencoded digital signal to the at least one encoder, based on the identifier, by at least one of a following decoder from a group consisting of:
the pre-decoder; and
the identified decoder;
transmitting a second unencoded digital signal, by the pre-decoder, to at least one of a following encoder from a group consisting of:
the at least one encoder; and
another one of the at least one encoder; and
converting, by the encoder, the first unencoded digital signal and the second un-encoded digital signal.

2. The method of claim 1 further comprising, if a final decoder is not available, transmitting, by the pre-decoder, the input signal to at least one of a following element from a group consisting of:
a default encoder; and
a default decoder.

3. The method of claim 1 further comprising assessing, by the pre-decoder, processing requirements of at least one of a following element from a group consisting of:
the first decoder;
the other decoder;
the at least one encoder;
the decoder;
the encoder;
the identified decoder; and
the another one of the at least one encoder.

4. The method of claim 3, further comprising deciding, by the pre-decoder, whether the received input signal is transmittable, based on the processing requirements, to at least one of a following element from a group consisting of:
the first decoder;
the other decoder;
the at least one encoder;
the decoder;
the encoder;
the identified decoder; and
the another one of the at least one encoder.

5. The method of claim 4, further comprising, if the received input signal is transmittable, transmitting, by the pre-decoder, the received input signal to at least one of a following element from a group consisting of:
the first decoder;
the other decoder;
the at least one encoder;
the decoder;
the encoder;
the identified decoder; and
the another one of the at least one encoder.

6. The method of claim 4, further comprising, if the received input signal is not transmittable, storing, by the pre-decoder, the received input signal to a first memory.

7. The method of claim 6, further comprising, assigning, by the pre-decoder, a higher priority to the stored received input signal than a new received input signal.

8. The method of claim 7, further comprising, transmitting, by the pre-decoder, the stored received input signal before the new received input signal to at least one of a following element from a group consisting of:
the first decoder;
the other decoder;
the at least one encoder;
the decoder;
the encoder;
the identified decoder; and
the another one of the at least one encoder.

9. The method of claim 8, further comprising storing the unencoded signal, by the identified decoder, in a second memory.

10. The method of claim 8, further comprising transmitting the unencoded signal, by the identified decoder, to an encoder based on the identifier, of the at least one encoder that is in at least one of a following state:
available; and
able to process the unencoded signal.

11. The method of claim 10, further comprising converting, by the encoder based on the identifier, the unencoded signal to an encoded signal.

12. The method of claim 11, further comprising storing the encoded signal in a third memory.

13. The method of claim 12, further comprising transmitting the encoded signal from the third memory to a collector.

14. The method of claim 13, further comprising transmitting, by the collector, the encoded signal to a transmitter.

15. The method of claim 13, further comprising storing, by the collector, the encoded signal in a fourth memory.

16. The method of claim 15, further comprising accessing, by a pre-module, the stored encoded signal from the fourth memory.

17. The method of claim 16, further comprising transmitting, by the pre-module the accessed encoded signal to a fifth memory.

18. The method of claim 17, wherein the accessed encoded signal is an un-synchronized encoded signal.

19. The method of claim 16, further comprising transmitting indexing properties from an index information module to the pre-module.

20. The method of claim 19 further comprising transmitting an un-synchronized encoded signal with indexing properties to the fifth memory.

21. The method of claim 16, further comprising determining, by the pre-module, a storage scheme for the stored encoded signal in the fifth memory based on the identifier.

22. The method of claim 20, further comprising determining, by the pre-module, a storage scheme for the un-synchronized encoded signal with indexing properties in the fifth memory.

23. The method of claim 17, further comprising receiving at least one of a following signal at a logical synchronization module from a group consisting of:
a user request; and
a live broadcast request.

24. The method of claim 23, wherein if the user request is received, accessing, by the logical synchronization module from the fifth memory at least one of the following signal from a group consisting of:
the un-synchronized encoded signal; and
the un-synchronized encoded signal with indexing properties;
wherein a portion the un-synchronized encoded signal with indexing properties is accessed based on the indexing properties.

25. The method of claim 23, wherein if the live broadcast request is received, accessing, by the logical synchronization module, the stored encoded signal from the fourth memory.

26. The method of claim 24 further comprising synchronizing the at least one of the following signal.

27. The method of claim 26 further comprising at least one of a following action from a group consisting of:
transmitting the at least one of the following synchronized signal; and
encrypting the at least one of the following synchronized signal.

28. The method of claim 25 further comprising synchronizing the stored encoded signal.

29. The method of claim 28 further comprising at least one of a following action from a group consisting of:
transmitting the synchronized encoded signal; and
encrypting the synchronized encoded signal.

30. A method for converting a signal, comprising:
receiving an un-encoded signal at a pre-quantization module;
transforming the un-encoded signal into a pre-transformed signal at the pre-quantization module;
storing the pre-transformed signal in a first memory;
transmitting the stored pre-transformed signal to an energy separation module by the pre-quantization module;
separating the transmitted pre-transformed signal into at least one of a following signal from a group consisting of:
a significant energy signal adapted to be stored in a second memory operably coupled to a quantization module; and
an insignificant energy signal adapted to be stored in a third memory operably coupled to the quantization module;
transmitting the energy signals by the energy separation module to the quantization module;
receiving encoding parameters by the pre-quantization module;
storing the encoding parameters in the first memory;
accessing the encoding parameters by the quantization module;
quantizing, by the quantization module, the energy signals based on the encoding parameters;
wherein the quantizing produces quantized energy signals;
storing the quantized significant energy signal in a fourth memory;
storing the quantized insignificant energy signal in a fifth memory;
transmitting, by the quantization module, the stored quantized significant energy signal and the stored quantized insignificant energy signal, to an entropy encoder;
encoding the signals;
transmitting the signals to a signal collector; and
storing the signals, by the signal collector, to a sixth memory.

31. A method for converting a signal, comprising:
receiving, by a pre-decoder, at least one input signal;
identifying, by the pre-decoder, the received input signal;
transmitting, by the pre-decoder, the identifier to at least one of a following module, based on the identifier, from a group consisting of:
at least one decoder; and
a first encoder;
transforming, by the identified decoder, the received input signal into a first un-encoded signal;
transmitting the first un-encoded signal to at least one encoder, based on the identifier, by the at least one decoder;
transmitting a second un-encoded signal, by the pre-decoder, to the first encoder; and
converting, by the at least one encoder, the first un-encoded signal into a first encoded signal; and
converting, by the first encoder, the second un-encoded signal, into a second encoded signal.

32. A system adapted to transmit a signal, comprising:
a receiver adapted to receive a first signal;
a resolution module adapted to produce an un-coded signal based on the first signal, wherein the receiver is coupled to the resolution module;
a transform adapted to produce pulses and index segments based on the un-coded signal, wherein the transform is coupled to the resolution module;
a collection module adapted to receive and store the pulses and the index segments; and
a transmitter adapted to transmit at least one of a following data from a group consisting of:
the produced pulses and index segments; and
the stored pulses and index segments.

33. The system of claim 32, wherein the data is transmitted to another receiver.

34. The system of claim 32 further comprising a second receiver adapted to receive a second signal, wherein the second receiver is coupled to the collection module.

35. The system of claim 34 further comprising a memory coupled to the collection module.

36. The system of claim 35, wherein the collection module is adapted to query the memory based on the second signal.

37. The system of claim 36, wherein the collection module transmits the stored pulses and index segments to the transmitter based on results of the query.

38. The system of claim 32, wherein the resolution module is a 1 to N resolution module.

39. The system of claim 32, wherein the transform is at least one of a following transform from a group consisting of:
reflective array;
discrete cosine;
wavelet;
fractal; and
any other signal processing transform.

40. The system of claim 32, wherein the first signal comprises at least one signal from a group consisting of:
the first signal as a whole;
a portion of the first signal; and
a plurality of signals including the first signal.

41. The system of claim 34, wherein the second signal comprises at least one signal from a group consisting of:
the second signal as a whole;
a portion of the second signal; and
a plurality of signals including the second signal.

42. A system adapted to transmit a signal, comprising:
a receiver adapted to receive a first signal and produce a buffered signal;
a transform adapted to produce pulses and index segments based on the buffered signal, wherein the transform is coupled to the receiver;
a collection module adapted to receive and store the pulses and the index segments; and
a transmitter adapted to transmit at least one of a following data from a group consisting of:
the produced pulses and index segments; and
the stored pulses and index segments.

43. A system adapted to transmit a signal, comprising:
a receiver adapted to receive a first signal;
a resolution module adapted to produce an un-coded signal based on the first signal, wherein the receiver is coupled to the resolution module;
a transform adapted to produce pulses and index segments based on the un-coded signal, wherein the transform is coupled to the resolution module;
a collection module adapted to receive and store the pulses and the index segments;
a transmitter adapted to transmit at least one of a following data from a group consisting of:
the produced pulses and index segments; and
the stored pulses and index segments; and
at least one memory coupled to at least one of a following element from a group consisting of:
the receiver;
the resolution module;
the transform;
the collection module; and
the transmitter.

44. A pre-quantization module, comprising:
means for filtering at least one of a following first signal from a group comprising of:
an un-encoded signal; and
an encoded signal;
means for filtering a second filtered signal, wherein the second filtered signal is related to the first filtered signal;
means for filtering a third filtered signal, wherein the third filtered signal is related to the second filtered signal; and
means for transforming the third filtered signal, wherein the transformed third filtered signal is output from the pre-quantization module.

45. The pre-quantization module of claim 44, wherein the means for filtering the first signal comprises bandpass filtration, wherein the bandpass filtration produces the first filtered signal.

46. The pre-quantization module of claim 44, wherein the means for filtering the second filtered signal comprises edge artifact filtration.

47. The pre-quantization module of claim 44, wherein the means for filtering the third filtered signal comprises anti-aliasing filtration.

48. The pre-quantization module of claim 44, wherein the means for transforming the third filtered signal comprises clarification transformation.

49. An energy separation module, comprising:
means for receiving a pre-transform signal;
means for buffering the pre-transform signal; and
means for receiving the buffered signal and dividing the buffered signal into at least one energy separated pulse band.

50. The energy separation module of claim 49, wherein the at least one energy separated pulse band is at least one of a following band from a group consisting of:
a significant pulse band; and
an insignificant pulse band.

51. The energy separation module of claim 49, wherein the means for buffering further comprises means for outputting the pre-transform signal to a memory until the pre-transform signal is entirely received.

52. The energy separation module of claim 51, wherein the means for buffering further comprises means for outputting the entirely received buffered signal from the memory.

53. A shear energy module, comprising:
means for receiving at least one of a following pulse band from a group comprising of:
a significant pulse band; and
an insignificant pulse band;
means for averaging amplitudes of the pulse band;
means for transforming the averaged pulse into a phase coded pulse; and
means for reflecting the phase coded pulse onto itself.

54. The shear energy module of claim 53 further comprising means for receiving the reflected phase coded pulse.

55. The shear energy module of claim 54 further comprising means for:
analyzing the received reflected phase coded pulse; and
realigning the received reflected phase coded pulse based on the analyzing.

56. The shear energy module of claim 55 further comprising means for outputting the realigned reflected phase coded pulse.

57. The shear energy module of claim 53, wherein the means for reflecting comprises means for separating at least one high pass and low pass filter coefficient.

58. The shear energy module of claim 53 further comprising means for buffering at least a portion of the reflected phase coded pulse until the reflected phase coded pulse is entirely received.

59. The energy separation module of claim 58 further comprising means for outputting the entirely received reflected phase coded pulse.

60. A computer readable medium comprising instructions for:
outputting a signal request;
transmitting the signal request;
receiving an input waveform and error enhancing signal based on the transmitted signal request;
transforming the received input waveform and error enhancing signal from a phase coded pulse to a presentation signal; and
transmitting the presentation signal based on the transformed input waveform and error enhancing signal.

61. The computer readable medium of claim 60, wherein the presentation signal is transmitted to a target device.

62. A computer readable medium comprising instructions for:
receiving an output waveform and error enhancement signal;
producing enhanced coefficient trees based on the received output waveform and error enhancement signal;
un-aligning the enhanced coefficient trees; and
producing a transformed pulse based on the un-aligned enhanced coefficient trees.

63. The computer readable medium of claim 62 comprising instructions for recovering the transformed pulse.

64. The computer readable medium of claim 63 comprising instructions for producing at least one pulse based on the recovered transformed pulse.

65. The computer readable medium of claim 64 comprising instructions for combining the at least one pulse.

66. The computer readable medium of claim 65 comprising instructions for producing a standing pulse based on the combined at least one pulse.

67. The computer readable medium of claim 66 comprising instructions for reversing the standing pulse.

68. The computer readable medium of claim 67 comprising instructions for producing a reconstructed signal based on the reversed standing pulse.

69. The computer readable medium of claim 68 further comprising transmitting the reconstructed signal to at least one of a following element:
an output module; and
a target device.

70. The computer readable medium of claim 69 comprising instructions for enhancing the reconstructed signal.

71. The computer readable medium of claim 70 comprising instructions for producing a filtered signal based on the enhanced reconstructed signal.

72. The computer readable medium of claim 71 comprising instructions for increasing an intensity of at least one segment of the filtered signal

73. The computer readable medium of claim 72 comprising instructions for producing a filtered reconstructed signal based on the increased intensity.

74. The computer readable medium of claim 62, wherein if the received output waveform and error enhancement signal is encrypted, decrypting the encrypted signal.

75. The computer readable medium of claim 62 further comprising instructions for producing an error recovery signal based on the decrypted output waveform and error enhancement signal.

76. The computer readable medium of claim 75 further comprising instructions for applying the error recovery signal to the un-aligned enhanced coefficient trees.

77. The computer readable medium of claim 76 further comprising instructions for producing a transformed pulse based on the error recovery signal.

78. The computer readable medium of claim 62 further comprising buffering at least one of a following waveform from a group consisting of:
the output waveform and error enhancement signal;
the decrypted output waveform and error enhancement signal; and
the transformed pulse.
